(19) United States
(12) Patent Application Publication
(10) Pub. No.: US 2024/0145309 A1
(43) Pub. Date: May 2, 2024

(54) STACKED WAFER AND DICING METHOD OF STACKED WAFER

(71) Applicant: CANON KABUSHIKI KAISHA, Tokyo (JP)

(72) Inventors: TETSURO YASUKAWA, Chiba (JP); TAKESHI SHIBATA, Kanagawa (JP); MASATAKA KATO, Kanagawa (JP)

(21) Appl. No.: 18/495,602

(22) Filed: Oct. 26, 2023

(30) Foreign Application Priority Data
Oct. 31, 2022 (JP) 2022-174219

(51) Int. Cl. H01L 21/78; H01L 21/67

(52) U.S. Cl. CPC H01L 21/78; H01L 21/67132

(57) ABSTRACT

A stacked wafer to be subjected to singulation by stealth dicing, including a first layer in which a modified region is formable, a concave portion forming a space facing the first layer, a second layer that faces the concave portion and in which the modified region is not formed, and a third layer that faces the second layer and in which the modified region is formable, and a part of the second layer facing the concave portion is removed.

### BACKGROUND

### Field

The present disclosure relates to a stacked wafer and a dicing method of the stacked wafer.

### Description of the Related Art

In recent years, there is a demand to highly accurately cleave a multilayer wafer in a dicing step, and stealth dicing is known as a dicing method of a wafer.

The stealth dicing is a dicing method of focusing laser light with an objective lens optical system and irradiating a wafer with the laser along a predetermined dicing line. Specifically, irradiating the wafer with the laser such that the laser is focused at a predetermined depth of the wafer forms a modified region (region with low crystal strength) at the predetermined depth. Then, irradiation or scanning is performed at multiple predetermined depths by varying the focal length of the laser, and a layer of multiple modified regions is thereby formed in the wafer. Then, force is applied from the outside by an expansion step or the like with the formed multiple modified regions being starting points. Applying force from the outside forms a crack extending in a thickness direction of the wafer, and can divide the wafer. The stealth dicing is a method of cutting a wafer in a non-contact manner in a dry process, and can suppress damages and soiling in the wafer.

Japanese Patent Laid-Open No. 2006-286727 discloses a stealth dicing method of a multilayer wafer. According to Japanese Patent Laid-Open No. 2006-286727, among layers on a dicing line along which laser light irradiation is planned, a layer that is located on the laser light entrance side and that is a layer (modified region non-formation layer) other than a layer (modified region formation layer) for forming modified regions is removed before the laser light irradiation. The entering laser light can thereby enter the wafer without being reflected or scattered by the modified region non-formation layer, and form the modified regions. Accordingly, appropriate cleavage using the modified regions at appropriate positions can be performed.

Among multilayer wafers, there is a stacked wafer in which multiple substrates such as an ink channel substrate, an ink ejection substrate, and an ejection energy generation substrate are joined to one another, like a wafer in which inkjet printing elements are formed. Among such stacked wafers, there is a stacked wafer including a hollow portion as a result of joining of a flat surface substrate and a recess substrate. For example, in the case where a substrate with terminals for electrical connection with the outside is to be joined, the flat surface substrate and the recess substrate are joined to form the hollow portion such that a region where the terminals are installed does not come into contact with the substrates. Moreover, in some cases, depending on the structure of the wafer, the wafer includes a layer in which the modified regions are difficult to form by the laser irradiation such as, for example, a layer in which a silicon on insulator (SOI) layer is formed as a layer facing the hollow portion.

In the stealth dicing of the stacked wafer including the hollow portion as described above, the hollow portion needs to be exposed. Accordingly, the wafer needs to cleaved such that cracks are connected to each other via the hollow portion.

However, in the cleavage of the wafer via the hollow portion, even in the case where reflection and scattering of laser are prevented by using the technique of Japanese Patent Laid-Open No. 2006-286727, there is a possibility that a crack formed in the modified region formation layer stops at the hollow portion at a midway position during application of force from the outside by the expansion step or the like. Particularly, in the case where a modified region non-formation layer that is the layer other than the modified region formation layer is present as the layer facing the hollow portion, since the modified region formation layer to be a source of a crack is absent around the hollow portion facing the modified region non-formation layer, it difficult to connect cracks to each other via the hollow portion. Thus, a cleavage property or a cleavage accuracy of the wafer may decrease.

### SUMMARY

The present disclosure provides a means by which to cause cracks to be connected to each other in cleavage in the case where a layer other than a modified region formation layer is present as a layer facing a hollow portion of a stacked wafer in stealth dicing of the stacked wafer including the hollow portion.

An embodiment of the present disclosure is a stacked wafer to be subjected to singulation by stealth dicing, the stacked wafer including a first layer in which a modified region is formable, a concave portion forming a space that faces the first layer, a second layer that is a layer facing the concave portion and in which the modified region is not formed, and a third layer that is a layer facing the second layer and in which the modified region is formable, in which a part of the second layer facing the concave portion is removed.

Further features of the present disclosure will become apparent from the following description of embodiments with reference to the attached drawings.

### BRIEF DESCRIPTION OF THE DRAWINGS

FIG. 1 is a flowchart of stealth dicing;

FIG. 2 is a perspective diagram illustrating an entire structure of a wafer in a first embodiment;

FIGS. 3A and 3B are perspective diagrams illustrating an entire structure of a chip in the first embodiment;

FIG. 4 is a cross-sectional diagram illustrating a layer structure of the wafer in the first embodiment;

FIG. 5 is a cross-sectional diagram illustrating details of the layer structure of the wafer in the first embodiment;

FIGS. 6A and 6B are schematic diagrams illustrating a dividing step of a conventional wafer;

FIGS. 7A and 7B are schematic diagrams illustrating a dividing step of the wafer in the first embodiment; and

FIG. 8 is a cross-sectional diagram illustrating details of a layer structure of a wafer in a second embodiment.

### DESCRIPTION OF THE EMBODIMENTS

Embodiments in the present disclosure are described below in detail with reference to the drawings. Note that dimensions, materials, and shapes of components, relative arrangement of the components, and the like that are described below should be changed as appropriate depending on various conditions, a configuration of an apparatus to which the technical idea of the present disclosure can be applied, and the like.

### <Method of Stealth Dicing>

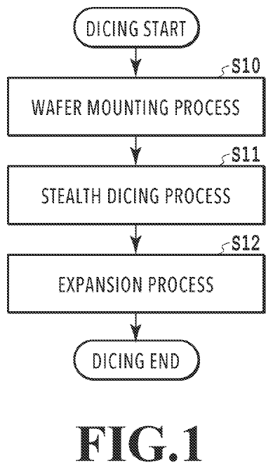

An outline of a method of stealth dicing is described below as a dicing method in the present disclosure. FIG. 1 is a flowchart of stealth dicing that can be adopted as the technical idea of the present disclosure.

As illustrated in FIG. 1, first, a wafer mounting process of mounting a wafer is performed in step S10. Specifically, a dicing tape is attached to one side of the wafer. The dicing tape is attached and fixed to a general dicing frame that is larger than an outer periphery of the wafer, and then attached to the wafer. The side on which the dicing tape is attached to the wafer may be any one of the sides of the wafer. The dicing tape is desirably a dicing tape that has adhesive force capable of holding the wafer in dicing and from which the wafer can be easily peeled off after cleavage. For example, it is possible to use a tape in which adhesive is cured by UV irradiation to allow reduction of the adhesive force after the dicing. Note that, in the following description, “step S” is abbreviated as “S”.

Next, in S11, a stealth dicing process of irradiating the wafer with laser is performed. Specifically, laser irradiation is performed along a predetermined dicing line set in the wafer. Moreover, a focal length of the laser is varied to irradiate the wafer with the laser at multiple depth, and multiple modified regions are thereby formed in the wafer in a direction orthogonal to the wafer surface (thickness direction of the wafer). Note that, in the case where the laser enters the wafer, the laser may enter the wafer from any one of the sides (any one of the side on which the dicing tape is attached and the side on which no dicing tape is attached). In the case where the laser enters from the side on which the dicing tape is attached, it is desirable to use a dicing tape with a high laser transmission property to appropriately adjust laser output and the like in consideration of laser attenuation caused by the dicing tape. Moreover, in the case where the wafer is to be irradiated with laser at a deep position in the thickness direction of the wafer or in the case where the laser passes multiple layers, the laser attenuates due to absorption and reflection in the wafer. Accordingly, there is a case where a laser attenuation amount in the wafer is large and the laser irradiation from one side cannot entirely irradiate the wafer in the thickness direction thereof. In such a case, it is effective to perform laser irradiation from both sides of the wafer, for example, perform laser irradiation from the opposite side with a certain portion in the wafer thickness direction being a border.

Lastly, in S12, the wafer is cleaved by an expansion process. Expanding the dicing tape at predetermined force forms cracks starting from the modified regions, the formed cracks are completely connected to one another over the entire range in the thickness direction of the wafer, and the wafer is cleaved. Note that a method of expansion is not limited to a particular method. For example, the wafer can be cleaved by expanding the dicing tape with an expander.

### First Embodiment

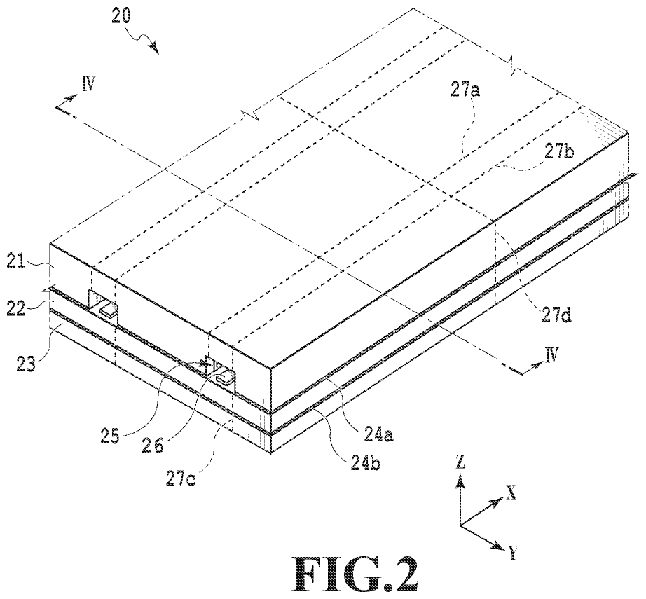

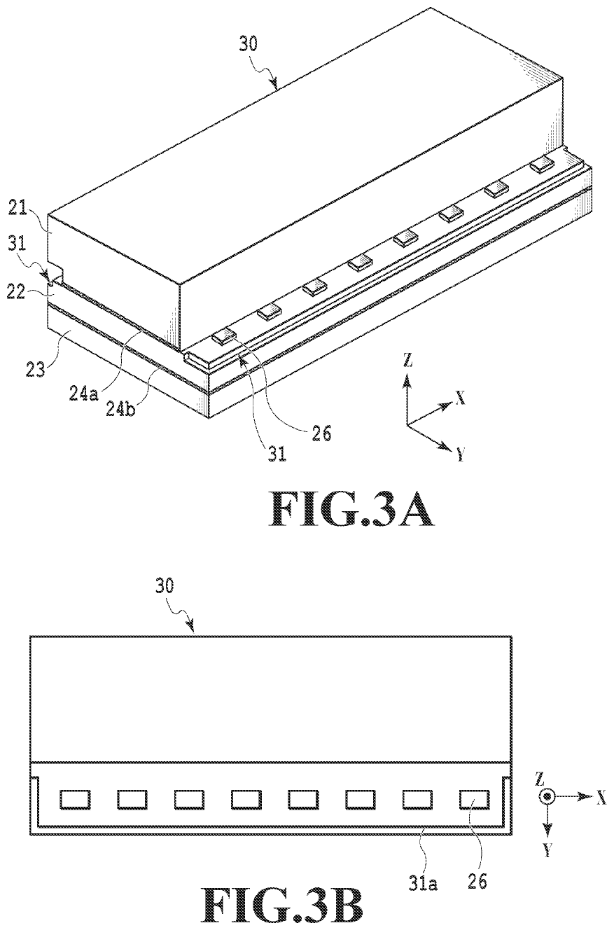

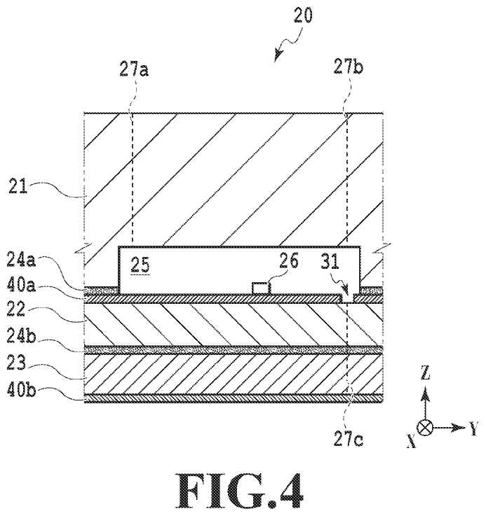

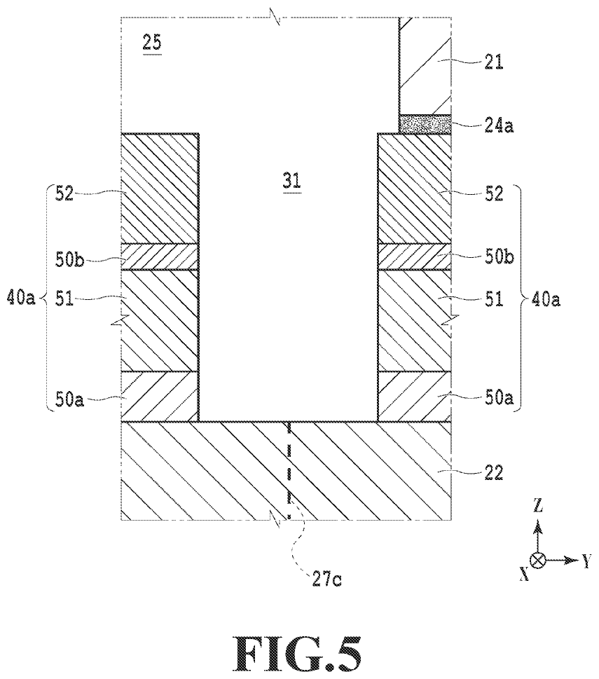

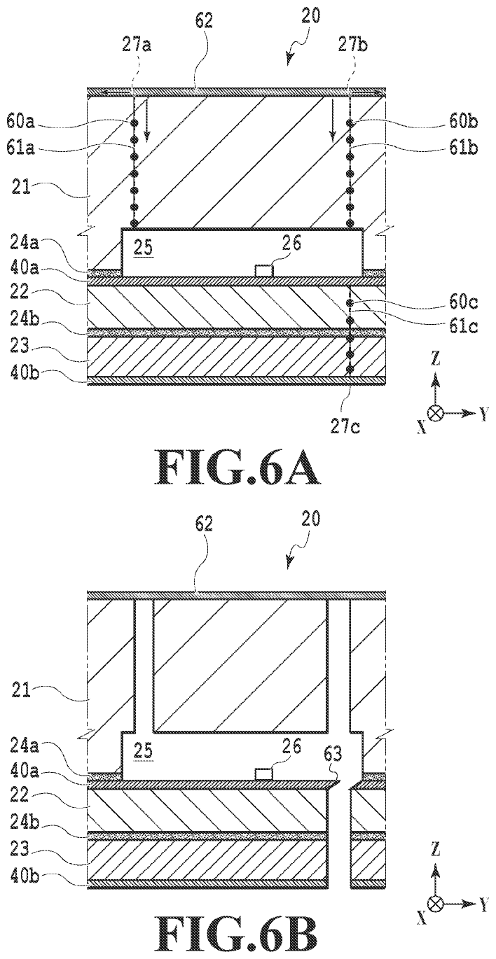

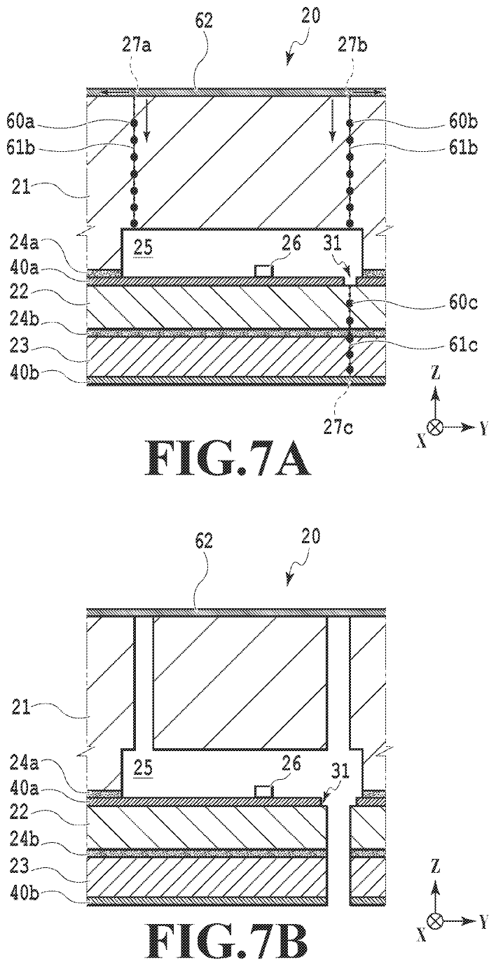

A first embodiment in the present disclosure is described below by using FIGS. 2 to 7B. FIG. 2 is a schematic diagram illustrating a wafer structure in the present embodiment. FIGS. 3A and 3B are schematic diagrams illustrating a chip structure in the present embodiment, FIG. 3A is a schematic diagram of a chip subjected to singulation after expansion, and FIG. 3B is a schematic diagram of the chip viewed from the upper side of FIG. 3A. FIG. 4 is a schematic cross-sectional diagram obtained in the case where a stacked wafer illustrated in FIG. 2 is cut along a cross-sectional line Iv-Iv. FIG. 5 is a schematic enlarged diagram illustrating a layer structure near a hollow portion illustrated in FIG. 4. FIGS. 6A and 6B and FIGS. 7A and 7B are schematic diagrams illustrating a dividing step of the wafer in the present embodiment. Specifically, FIGS. 6A and 7A are each a schematic diagram during the expansion, and FIGS. 6B and 7B are each a schematic diagram after the expansion.

FIG. 2 illustrates a stacked wafer 20 for inkjet in which multiple substrates are joined to one another. There are an ink channel substrate 21 in which an ink channel for guiding ink to ejection ports is formed, an energy generation element substrate 22 that is provided with energy generation elements for ejecting the ink from the ejection ports, and an ejection port substrate 23 in which the multiple ejection ports for ejecting the ink are formed. These substrates are joined to one another by adhesive layers 24. Specifically, the ink channel substrate 21 and the energy generation element substrate 22 are joined to each other by an adhesive layer 24a, and the energy generation element substrate 22 and the ejection port substrate 23 are joined to each other by an adhesive layer 24b. Note that, as illustrated in FIG. 2, a direction in which multiple terminals 26 are aligned in the hollow portion is referred to as X direction, a thickness direction of the stacked wafer 20 is referred to as Z direction, and a direction orthogonal to the X direction and the Z direction is referred to as Y direction. Note that the ink channel substrate 21 is defined as “first layer” and the energy generation element substrate 22 is defined as “third layer”.

The ink channel substrate 21 has a structure including a recess portion. The energy generation element substrate 22 is joined to the ink channel substrate 21 to cover the recess portion, and a hollow portion 25 is thereby formed. The terminals 26 are terminals to be electric connection portions for electric connection with the outside for supplying electric power to the energy generation elements, and multiple terminals 26 are formed in the hollow portion 25. Dicing lines 27 (27a, 27b, 27c, and 27d) are laser irradiation lines for singulation of the stacked wafer 20 into chips, and the stacked wafer 20 is irradiated with the laser in the predetermined depth direction along the dicing lines 27. A rectangular parallelepiped region of the ink channel substrate 21 surrounded by the dicing lines 27a and 27b and the hollow portion 25 is an unnecessary portion, and is a region removed after the dicing. As illustrated in FIG. 4, the Y direction positions of the respective dicing lines 27a and 27b are within a (Y direction) region of the hollow portion 25 so that the unnecessary portion can be surely removed. In the present embodiment, since a dicing tape for indicating the dicing lines is attached on the ink channel substrate 21 side, this unnecessary region is left on the dicing tape and is disposed. Moreover, the wafer is irradiated with the laser from both sides with the hollow portion 25 being the border. A flow is such that the wafer is irradiated with the laser from one side, is turned over, and is irradiated with the laser from the other side. Note that, in the cutting with the laser irradiation, the order may be such that the first side from which the laser irradiation is to be performed may be either side.

FIG. 3A is a schematic perspective diagram of a chip 30 obtained by the singulation of the stacked wafer 20. A region of the ink channel substrate 21 surrounded by the dicing lines 27a and 27b and the hollow portion 25 illustrated in FIG. 2 is removed, and the terminals 26 are exposed. As illustrated in FIGS. 3A, 3B, and 4, a layer removal region 31 facing the hollow portion 25 is present at an end of the chip 30 of an exposed surface. As illustrated in FIGS. 4 and 5, the layer removal region 31 forms a step shape on the surface of the energy generation element substrate 22, and is removed by etching or the like before the dicing. Presence of the layer removal region can improve a cleavage property and cleavage accuracy in the dicing also in the case where a layer other than a modified layer formed region is present while facing the hollow portion 25.

A structure of the layer removal region 31 facing the hollow portion 25 is described below in detail. As illustrated in FIG. 4, in the stacked wafer 20, modified region non-formation layers 40 (40a, 40b) are formed as a plurality of layers other than a modified region formation layer. A first modified region non-formation layer 40a and a second modified region non-formation layer 40b are present as the modified region non-formation layers 40. The dicing line 27c is aligned to reach the layer removal region 31 facing the hollow portion 25. The layer removal region 31 is a region obtained by removal of a part of the first modified region non-formation layer 40a facing the hollow portion 25. Note that the first modified region non-formation layer 40a is defined as “second layer”. As illustrated in FIG. 4, the first modified region non-formation layer 40a includes a first portion that faces the hollow portion 25 and that defines the region of the hollow portion 25 and a second portion that does not face the hollow portion 25.

As illustrated in FIG. 5, in the present embodiment, the first modified region non-formation layer 40a facing the hollow portion 25 is formed of oxide films 50 (50a and 50b) and a Silicon On Insulator (SOI) layer being a thin silicon layer 51 that are upper layers of the energy generation element substrate 22. The SOI layer functions as a stop layer for suppressing film thickness distribution in etching in formation of function modules necessary for inkjet printing elements. One or more layers of multiple films 52 such as a protection layer are formed in the upper layer of the SOI layer. The first modified region non-formation layer 40a does not have a film thickness large enough for modification with the laser, and absorbs almost no laser depending on the material. Accordingly, the first modified region non-formation layer 40a is a layer in which formation of the modified region is difficult. Particularly, since the first modified region non-formation layer 40a is configured to include, though thin, the SOI layer, there is a concern of a decrease in the cleavage property or the cleavage accuracy. The reason for this is as follows. The modified regions can be formed in a silicon layer, and the cleavage is generally performed with the modified regions being starting points. Meanwhile, cleaving the SOI layer without the formation of the modified regions means forcedly cleaving the SOI layer that is difficult to cleave.

Accordingly, in the present embodiment, the layer removal region 31 facing the hollow portion 25 is formed. In detailed description, the first modified region non-formation layer 40a (including the SOI layer) from an upper surface of the energy generation element substrate 22 to the hollow portion 25 is entirely removed over a predetermined range whose center is the dicing line 27c. Moreover, the layer removal region 31 facing the hollow portion 25 is arranged in consideration that the adhesive layer 24a does run over and enter the layer removal region 31. In the present embodiment, the first modified region non-formation layer 40a is removed in a range of ±8 μm from the dicing line 27c in the Y direction, and a distance from an end portion of the ink channel substrate 21 to the dicing line 27c in the Y direction is 17.5 μm. As described above, the removal region of the first modified region non-formation layer 40a is away from the end portion of the region of the hollow portion 25 by a predetermined distance. Note that the layer other than the modified region formation layer is removed also in a periphery of the hollow portion 25 in cleavage in the direction of the dicing line 27d orthogonal to the dicing line 27c, based on an idea similar to that of the dicing line 27c.

Note that, in the present embodiment, the second modified region non-formation layer 40b facing the ejection port substrate 23 is not removed. The oxide films 50 (50a and 50b) and the SOI layer being the thin silicon layer 51 are formed in the second modified region non-formation layer 40b as in the first modified region non-formation layer 40a facing the hollow portion 25, and the one or more layers of multiple films 52 such as a protection layer may be formed. Moreover, although the dicing line 27b and the dicing line 27c are on the same straight line as illustrated in FIG. 4, the dicing line 27c may be arranged at another position that is not on the same straight line as the dicing line 27b. For example, the dicing line 27c may be arranged at the center of the hollow portion 25. In this case, the shape of the chip after the cleavage is an inverted T-shape in which both ends of the chip are exposed, instead of the L-shape in which one side is exposed as in the chip 30 illustrated in FIG. 3A. Accordingly, multiple terminals 26 are aligned in the X direction in each of both chip ends.

### <Effects of Providing Layer Removal Region>

Next, effects of the layer removal region 31 in the expansion step are described.

For comparison with the present embodiment, description is first given of the case where there is no layer removal region 31 facing the hollow portion 25 as in FIG. 6A, that is the case where the cleavage property and the cleavage accuracy decrease due to provision of no layer removal region 31.

As illustrated in FIG. 6A, a dicing tape 62 is attached to the ink channel substrate 21. Moreover, modified regions 60a are formed on the dicing line 27a, and modified regions 60b are formed on the dicing line 27b by laser irradiation. As a result of pulling of the dicing tape 62 to right and left by the expansion as illustrated by the arrows in FIG. 6, a crack 61a passing the multiple modified regions 60a and a crack 61b passing the multiple modified regions 60b are formed. As illustrated by the downward arrows in FIG. 6A, a direction in which the crack 61a and the crack 61b are formed spreads over the entire range in the thickness direction of the stacked wafer 20 (Z axis direction) with the expanded dicing tape 62 being the starting point. In the cleavage, the crack 61b formed in the ink channel substrate 21 temporarily stops at the hollow portion 25. A portion to which the crack 61b is connected again is on a line connecting the multiple modified regions 60c formed along the dicing line 27c, but the first modified region non-formation layer 40a is present as a layer that faces the hollow portion 25 and that is a starting point of a crack 61c. Accordingly, the crack 61b stopping at the hollow portion 25 is less likely to be connected to an appropriate position in a lower layer of the hollow portion 25. As a result, there is a possibility that the cleavage is performed with the crack meandering in the first modified region non-formation layer 40a and a cleavage failure 63 occurs as illustrated in FIG. 6B, or that the cleavage cannot be performed at all in the first place.

Meanwhile, as illustrated in FIG. 7A, in the case where the layer removal region 31 is provided to face the hollow portion 25, the crack 61b formed from the dicing tape 62 side stops at the hollow portion 25, but the layer removal region 31 is present at a location to be the starting point of the crack 61c across the hollow portion 25. In other words, since the energy generation element substrate in which the multiple modified regions 60c are provided is present immediately across the hollow portion 25 instead of the first modified region non-formation layer 40a, the crack 61b is more likely to be connected to the crack 61c at an appropriate position via the hollow portion. Accordingly, as illustrated in FIG. 7B, the cleavage property and the cleavage accuracy are improved from those in FIG. 6B.

Note that, regarding the second modified region non-formation layer 40b facing the ejection port substrate 23, since there is no hollow portion facing the second modified region non-formation layer 40b, the crack propagates on the line connecting the multiple modified regions 60c without stopping in the cleavage. Accordingly, even in the case where the second modified region non-formation layer 40b is not partially removed, this does not become a big problem as in the first modified region non-formation layer 40a facing the hollow portion 25.

### Effects of Present Embodiment

As described above, in the present embodiment, the layer removal region 31 is provided by removing the first modified region non-formation layer 40a facing the hollow portion 25. This provides the following effect. In the cleavage, the crack 61b formed in the ink channel substrate 21 from the dicing tape 62 side stops at the hollow portion 25 but, since the modified regions 60c to be the starting points of the crack 61c are present in a portion across the hollow portion 25, the crack formed in the ink channel substrate 21 is more likely to be connected to the crack formed on the extended line of the crack formed in the ink channel substrate 21. In other words, cracks are more likely to be connected to each other even in the case where the cracks are connected via the hollow portion 25. Accordingly, in the case where there is the first modified region non-formation layer 40a facing the hollow portion 25 in the stealth dicing of the stacked wafer 20 including the hollow portion 25, it is possible to improve the cleavage property and the cleavage accuracy in the wafer cleavage.

### Second Embodiment

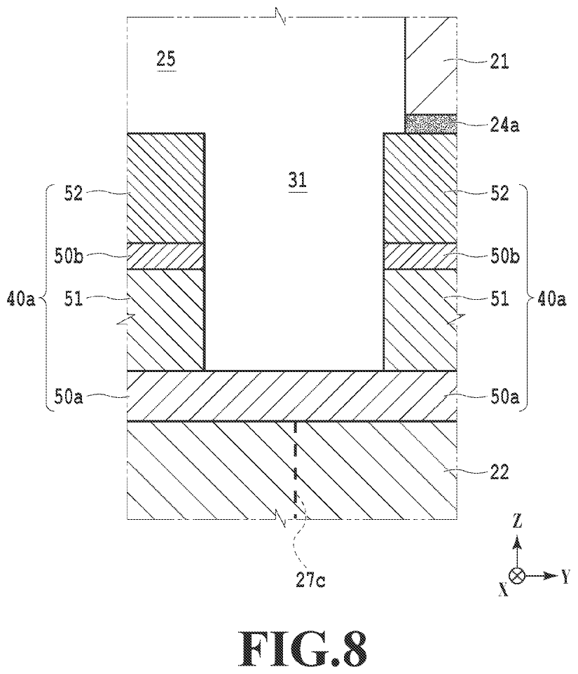

A second embodiment is described below by using FIG. 8. FIG. 8 is a cross-sectional diagram of a stacked wafer in the present embodiment, and is a schematic diagram in which a layer structure around the hollow portion 25 and the layer removal region 31 is illustrated in an enlarged manner. As illustrated in FIG. 8, the present embodiment is different from the first embodiment (see FIG. 5) in the layer structure of the first modified region non-formation layer 40a around the layer removal region 31 facing the hollow portion 25.

Generally, modified regions are formed in a silicon layer, and the silicon layer is cleaved. Cleaving the silicon layer without formation of the modified regions means forcedly cleaving an object that is difficult to cleave, and there is a concern of a decrease in the cleavage property or the cleavage accuracy. Accordingly, the present embodiment has such a configuration that not all of the layers included in the first modified region non-formation layer 40a facing the hollow portion 25 and being the layer 40 other than the modified region formation layer are removed, and at least the thin silicon layer 51 that tends to be a factor causing a cleavage failure is removed. Since the first modified region non-formation layer 40a facing the hollow portion 25 is partially left, the present embodiment has a cleavage property slightly inferior to that in the first embodiment, but can reduce time required for layer removal from that in the first embodiment.

### Effects of Present Embodiment

In the present embodiment, the thin silicon layer 51 that is considered to tend to be a factor causing a cleavage failure in the first modified region non-formation layer 40a facing the hollow portion 25 and being the layer other than the modified region formation layer is removed, while other layers (films) included in the first modified region non-formation layer 40a are left. This can reduce time required for layer removal while maintaining the cleavage property of the wafer.

According to the present disclosure, in the stealth dicing of the stacked wafer including the hollow portion, the cracks are more likely to be connect to each other in the cleavage also in the case where the layer other than the modified region formation layer is present as the layer facing the hollow portion of the stacked wafer. Accordingly, the cleavage property and the cleavage accuracy of the wafer can be improved.

While the present disclosure has been described with reference to embodiments, it is to be understood that the disclosure is not limited to the disclosed embodiments. The scope of the following claims is to be accorded the broadest interpretation so as to encompass all such modifications and equivalent structures and functions.

This application claims the benefit of priority from Japanese Patent Application No. 2022-174219, filed Oct. 31, 2022, which are hereby incorporated by reference wherein in its entirety.

What is claimed is:

1. A stacked wafer to be subjected to singulation by stealth dicing, the stacked wafer comprising:
a first layer in which a modified region is formable;
a concave portion forming a space that faces the first layer;
a second layer that is a layer facing the concave portion and in which the modified region is not formed; and
a third layer that is a layer facing the second layer and in which the modified region is formable, wherein
a part of the second layer facing the concave portion is removed.

2. The stacked wafer according to claim 1, wherein
the second layer includes a first portion that faces the hollow portion and that defines a region of the hollow portion and a second portion that does not face the hollow portion, and
the part of the second layer is a part of the first portion.

3. The stacked wafer according to claim 1, wherein removal of the part of the second layer exposes the third layer to the hollow portion.

4. The stacked wafer according to claim 1, wherein,
in a case where a direction in which a plurality of terminals are aligned in the hollow portion is referred to as X direction, a thickness direction of the stacked wafer is referred to as Z direction, and a direction orthogonal to the X direction and the Z direction is referred to as Y direction,
the part of the second layer is removed along a dicing line in the X direction.

5. The stacked wafer according to claim 1, wherein
in a case where a direction in which a plurality of terminals are aligned in the hollow portion is referred to as X direction, a thickness direction of the stacked wafer is referred to as Z direction, and a direction orthogonal to the X direction and the Z direction is referred to as Y direction,
a distance between an end portion of a region of the hollow portion and the part of the second layer in the Y direction is a predetermined distance.

6. The stacked wafer according to claim 1, wherein
the second layer includes a Silicon On Insulator (SOI) layer and an oxide film, and
the SOI layer is removed by removal of the part of the second layer.

7. The stacked wafer according to claim 6, wherein the oxide film is removed by removal of the part of the second layer.

8. The stacked wafer according to claim 6, wherein the oxide film is not removed by removal of the part of the second layer.

9. The stacked wafer according to claim 1, further comprising a plurality of layers that do not face the hollow portion and in which the modified region is not formed, wherein
the plurality of layers are not removed.

10. A dicing method of subjecting a stacked wafer to singulation by stealth dicing, the stacked wafer including a first layer in which a modified region is formable as a cleavage region with low crystal strength, a hollow portion that faces the first layer, a second layer that is a layer facing the hollow portion and in which the modified region is not formed, and a third layer that is a layer facing the second layer and in which the modified region is formable, the second layer being such that a part of a portion of the second layer facing the hollow portion is removed, the dicing method comprising:
forming a plurality of the modified regions along a dicing line by performing laser irradiation while varying a focal length in a thickness direction of the stacked wafer; and
performing an expansion process on the stacked wafer in which the modified regions are formed, and cleaving the stacked wafer via the hollow portion along the dicing line.
